(19) United States
(12) Patent Application Publication
(10) Pub. No.: US 2012/0125256 A1
(43) Pub. Date: May 24, 2012

(54) APPARATUS AND METHOD FOR REPEATEDLY FABRICATING THIN FILM SEMICONDUCTOR SUBSTRATES USING A TEMPLATE

(75) Inventors: Karl-Josef Kramer, San Jose, CA (US); Mehrdad M. Moslehi, Los Altos, CA (US); David Xuan-Qi Wang, Fremont, CA (US); Subramanian Tamilmani, Milpitas, CA (US); Sam Tone Tor, Pleasanton, CA (US); Rahim Kavari, Campbell, CA (US); Rafael Ricolcol, Fremont, CA (US); George Kamian, Scotts Valley, CA (US); Joseph Leigh, Santa Clara, CA (US)

(73) Assignee: SOLEXEL, INC., Milpitas, CA (US)

(21) Appl. No.: 13/209,390

(22) Filed: Aug. 13, 2011

Related U.S. Application Data
(63) Continuation-in-part of application No. 11/868,493, filed on Oct. 6, 2007, now Pat. No. 8,035,028.
(60) Provisional application No. 61/373,793, filed on Aug. 13, 2010.

(51) Int. Cl. C30B 25/02

(52) U.S. Cl. 117/95

(57) ABSTRACT

Mechanisms are disclosed by which a semiconductor wafer, silicon in some embodiments, is repeatedly used to serve as a template and carrier for fabricating high efficiency capable thin semiconductor solar cells substrates. Mechanisms that enable such repeated use of these templates at consistent quality and with high yield are disclosed.

### CROSS-REFERENCE TO RELATED APPLICATIONS

This application claims priority to U.S. Provisional Patent Application Ser. No. 61/373,793 filed Aug. 13, 2010, which is hereby incorporated by reference in its entirety. This application is also a continuation-in-part of U.S. patent application Ser. No. 11/868,493 (published as U.S. Pub. No. 2008/0289684), filed Oct. 6, 2007, which is hereby incorporated by reference in its entirety.

### FIELD

This disclosure relates in general to the field of solar photovoltaics, and more particularly to the field of repeatedly fabricating thin film solar substrates from a semiconductor template.

### BACKGROUND

In the field of photovoltaics, this disclosure enables low cost fabrication of thin film substrates to be used for solar cell manufacturing by means of a template which can be used repeatedly to fabricate said thin film substrates. The field of this disclosure covers several apparatuses and methods for generating thin film substrates and for treating the templates which are used to produce the thin film substrates, with the goal of recovering the templates to enable an extended number of re-uses.

Crystalline silicon (including multi- and mono-crystalline silicon) is the most dominant absorber material for commercial photovoltaic applications. The relatively high efficiencies associated with mass-produced crystalline silicon solar cells, combined with the abundance of material, garner appeal for continued use and advancement. But the relatively high cost of crystalline silicon material itself limits the widespread use of these solar modules. At present, the cost of “wafering”, or crystallizing silicon and cutting a wafer, accounts for about 40% to 60% of the finished solar module manufacturing cost. If a more direct way of making wafers were possible, great headway could be made in lowering the cost of solar cells.

There are different known methods of growing monocrystalline silicon and releasing or transferring the grown wafer. Regardless of the methods, a low cost epitaxial silicon deposition process accompanied by a high-volume, production-worthy, low cost method of forming a release layer are prerequisites for wider use of silicon solar cells.

Another prerequisite is the availability of a re-usable template to repeatedly perform the sequence of release layer formation, thin film deposition, on-template processing, thin film layer release, recovery/reconditioning of template.

The microelectronics industry achieves economy of scale through obtaining greater yield by increasing the number of die (or chips) per wafer, scaling the wafer size, and enhancing the chip functionality (or integration density) with each successive new product generation. In the solar industry, economy is achieved through the industrialization of solar cell and module manufacturing processes with low cost high productivity equipment. Further economies are achieved through price reduction in raw materials through reduction of materials used per watt output of solar cells.

In order to achieve the necessary economy for the solar photovoltaics industry, process cost modeling is studied to identify and optimize equipment performance. Several categories of cost make up the total cost picture: Fixed Cost (FC), Recurring Cost (RC) and Yield Cost (YC). FC is made up of items such as equipment purchase price, installation cost and robotics or automation cost. RC is largely made up of electricity, gases, chemicals, operator salaries and maintenance technician support. YC may be interpreted as the total value of parts lost during production.

To achieve Cost of Ownership (CoO) numbers required by the solar field, all aspects of the cost picture must be optimized. The qualities of a low cost process are (in order of priority): 1) High productivity, 2) High yield, 3) Low RC, and 4) Low FC.

Designing highly productive and economical methods and process equipment requires a good understanding of the process requirements and reflecting those requirements into the equipment architecture. High yield requires a robust process and reliable equipment and as equipment productivity increases, so too does yield cost. Low RC is also a prerequisite for overall low CoO. RC can impact plant site selection based on, for example, cost of local power or availability of bulk chemicals. FC, although important, is diluted by equipment productivity.

With the above said, in summary, a high productivity, reliable, efficient manufacturing process flow and equipment is a prerequisite for low cost solar cells.

### SUMMARY

The use of a reusable semiconductor template for the production of thin film semiconductor substrates (TFSSs) allows significant cost reduction in the field of solar photovoltaics. A sacrificial release layer is produced on the template, and then a TFSS is deposited on the sacrificial layer. However, when the TFSS is released from the template, residual film may be left behind. This disclosure deals primarily with ways of removing that residuum and preparing the template for reuse.

### BRIEF DESCRIPTION OF THE DRAWINGS

The features, nature, and advantages of the disclosed subject matter will become more apparent from the detailed description set forth below when taken in conjunction with the drawings, in which like reference numerals indicate like features and wherein:

FIGS. 1A-1C show one embodiment of the formation of surface features on a reusable semiconductor template;

FIG. 2A shows a patterned semiconductor template, a porous semiconductor multilayer, and a TFSS;

FIG. 2B shows an electron micrograph of a flat template and a sacrificial layer with two different porosities;

FIG. 3 shows an electron micrograph of the interface between a template and a TFSS;

FIG. 4 shows a TFSS ready to be released from a template;

FIG. 5A shows two templates with differing amounts of TFSS overdeposition;

FIG. 5B shows a TFSS being released from a template;

FIG. 5C shows a TFSS with overdeposition being removed from a template;

FIG. 5D shows the use of grinding tape to remove residual TFSS material from a template;

FIG. 5E shows the use of an edge grinder to remove residual TFSS material from a template;

FIG. 5F shows the use of a laser with a varying angle of incidence to remove residual TFSS material from a template; and

FIG. 5G shows the removal of excess front-side TFSS material by grinding.

### DETAILED DESCRIPTION

Although the present disclosure is described with reference to specific embodiments, one skilled in the art could apply the principles discussed herein to other areas and/or embodiments without undue experimentation.

This disclosure includes process flows, unit processes, and apparatuses, and variations thereof which enable the repeated use of a template that is used in the fabrication of thin film layers which subsequently are processed to become solar cells.

This disclosure includes a starting semiconductor wafer (called a template) with correct resistivity to enable anodization to form porous semiconductor material on one or both sides. The semiconductors used may include silicon, and in particular monocrystalline silicon. The template outline can be of any suitable shape, including round (with or without notches or flats), square, or pseudo-square with rounded or chamfered corners. The porous semiconductor material may consist of several layers with discrete or graded porosity. At least one section of the porous semiconductor layer system serves as a designated weakened layer that facilitates separation of the TFSS from the template.

This disclosure covers the use of a template for repeatedly fabricating thin crystalline solar cell substrates from the template; the solar cell substrates can be fabricated on one side of the template or on both sides of the template. Even though the figures in this disclosure specifically address the single sided processing, it is envisioned that all embodiments of the current disclosure hold essentially for the case of single sided substrate processing as well as for double side substrate processing.

Regarding the starting wafer, several structural architecture options exist which are described in the following. In the simplest embodiment, the template can be essentially flat, i.e. the surface can be of any chosen surface quality, such as for example as-sawn with saw damage removed, lapped or ground, etched or even mirror polished. In another embodiment, the wafer can be textured, using for instance alkaline random texturing before the formation of the above-described porous semiconductor layer system. By this means, a textured surface is then transferred directly onto the thin film solar cell substrate. As a third alternative, the template can receive a patterned three-dimensional structure. This three-dimensional structure may be achieved through the use of patterning technology, such as, but not exclusively, photolithography.

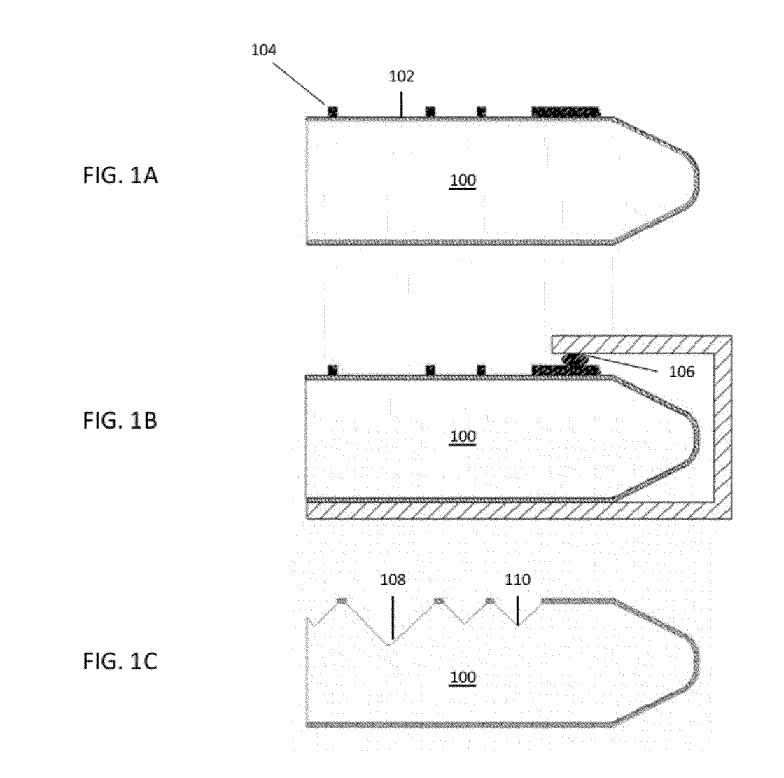

An example process is described in FIGS. 1A-1C. In FIG. 1A, a starting wafer 100 is provided. For the purpose of forming a 3-dimensional structure, typically, a hard mask is formed, using as materials for example, but not exclusively, thermal oxide or other deposited etch resistant layer or layers such as deposited silicon nitride or silicon oxide. Hard mask layer 102, is formed on the surface of wafer 100. Then the desired pattern of photoresist 104 is lithographically patterned onto hard mask layer 102. In FIG. 1B, the wafer is placed in a holder and sealed with O-ring 106 to protect all but the front surface. Then hard mask layer 102 is etched to produce the desired pattern, removing all hard mask except what lies underneath the remaining photoresist.

In FIG. 1C, a semiconductor etch process is employed, either through dry etching such as deep reactive ion etching (DRIE) or wet etching such as using an optionally heated concentrated alkaline wet etch with chemicals such as potassium hydroxide, sodium hydroxide, tetramethyl ammonium hydroxide (TMAH) or others. This creates the desired pattern on the surrface of the wafer, in this example including large inverted pyramidal structures 108 and small pyramidal structures 110. Finally, the photoresist and hard mask are stripped from the wafer, and the wafer is cleaned. It is then ready for the formation of porous semiconductor on the textured surface. Other, similar processes are easily derived from the figures by those skilled in the art.

A three-dimensional template patterning is depicted in most figures of this disclosure as it encompasses a larger realm of embodiments. However, unless otherwise noted, the figures, process flows, methods and apparatuses of this disclosure are equally applicable to flat or randomly textured templates.

With either a patterned or an un-patterned template prepared, the subsequent process step is porous semiconductor formation, followed by rinsing and drying where necessary. Porous semiconductor is to be formed on at least one side of the template. For the case that the semiconductor is silicon, the process of forming porous silicon has been described in previous disclosures, for example U.S. Patent Publication No. 2011/0030610, which is hereby incorporated by reference. Fundamentally, the porous semiconductor formation entails the fabrication of at least one lower porosity region 112 at the surface and at least one higher porosity layer 114 closer to the template.

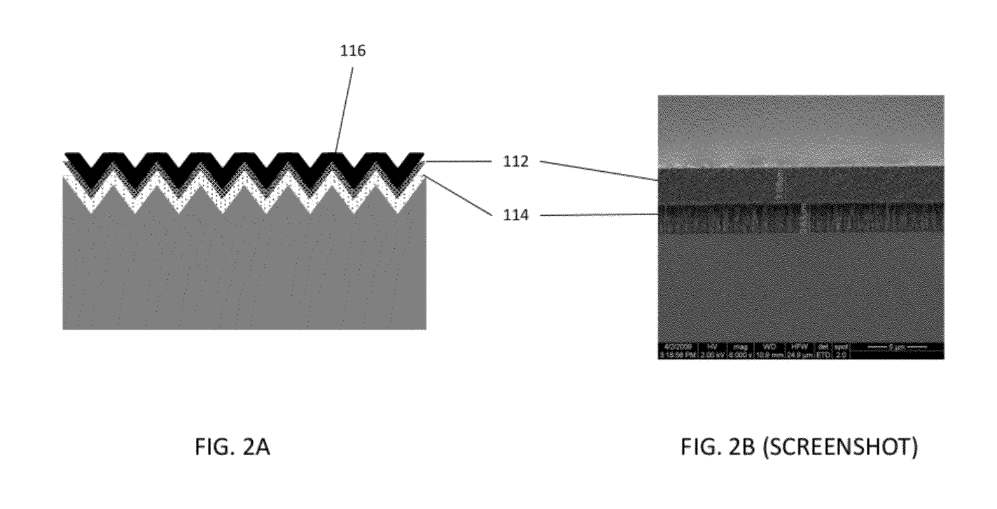

The template with the porous semiconductor layers formed is then transferred to an epitaxial deposition reactor, in which an epitaxial layer is deposited at least on one side of the template. FIG. 2A illustrates the deposition of epitaxial layer 116 on top of the porous semiconductor layer system. FIG. 2B shows a porous semiconductor bi-layer structure, with a lower porosity on top and a higher porosity below, in a flat template embodiment.

Before the deposition, either during the ramp-up phase or during a separate pre-deposition time, the template is kept in a hydrogen ambient which serves several purposes: the top layer of the porous semiconductor is reflowed to re-form a quasi-monocrystalline growth surface of semiconductor (QMS). Also, the hydrogen bake serves to reduce any oxidized surface semiconductor back to its elemental form. In addition, the high porosity semiconductor layer coalesces to form a weak layer which can later serve as the release boundary between the grown layer and the template.

If the semiconductor is silicon, then in the initial stages of the deposition or during the bake, the reflow can be assisted by small amounts of a non-chlorine-containing species such as silane or using very low flow quantities of other silicon-containing gases such as trichlorosilane (TCS). This is one option for a process component that serves to safely prevent a failure mechanism that may occur during imperfect reflow and which is described below.

There are potential failure mechanisms that can occur during reflow. Several mitigations to such failure mechanisms are part of this disclosure: as the template is heated up in the semiconductor deposition reactor, which can for example be an epitaxial reactor, the template touches the susceptor typically in a plurality of locations. These contact points can contribute to a non-ideality in the above-described reflow of the porous semiconductor layer. These contact points can also contribute to a local abrasion of the porous semiconductor layer. As a consequence, the porous semiconductor layer may contain local areas where it is not hermetic.

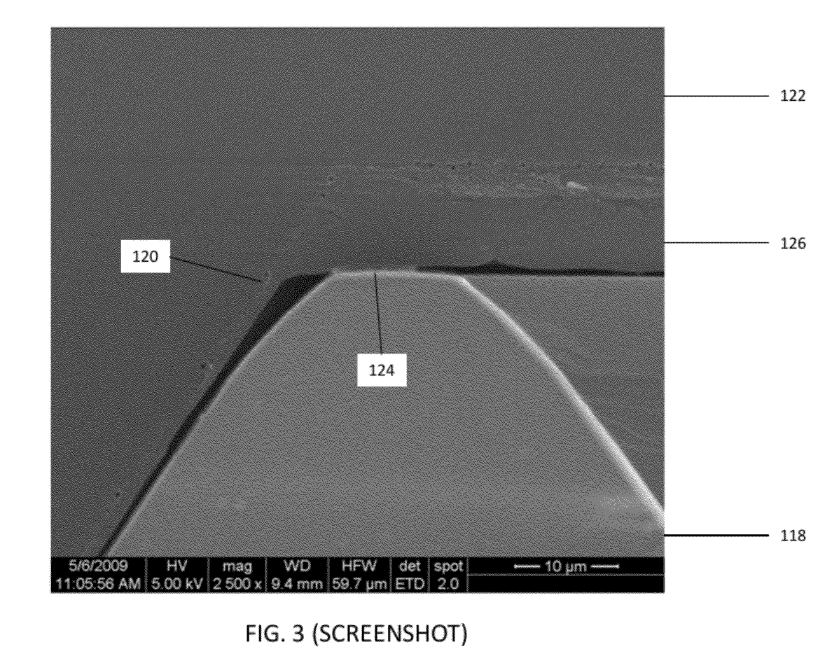

An example of a failure mechanism is illustrated in FIG. 3, which shows template 118, QMS layer 120 (which normally contains some entrapped holes), and deposited epitaxial layer 122. As the deposition starts after the reflow, two phenomena can be observed: a) deposition of material through QMS layer 120 and directly onto the template base. Fused spot 124 is an example of this phenomenon. Such areas lack a weakened sub-layer and thus resist the subsequent release process (described below). In cases where shortly after the onset of deposition, the non-hermetic region is sealed, there is a chance that deposition gas may be trapped in underneath the top deposition layer. Such deposition gases may contain etching components such as chlorine-containing species as byproducts of the deposition reaction of silicon from a TCS molecule. These byproducts can contribute to subsequent etching of the template material. The etched and volatized template material can redeposit on the top layer, thus re-releasing again the chlorine-containing species. In FIG. 3, some re-deposited template material 126 may be seen. Thus, in a quasi-sealed local environment the process can continue and template etching can be observed to be severe, up to several microns. One option to avoid this etching and re-deposition mechanism is to start the deposition using a reactant which does not have an etching species as a byproduct. An example for such a reactant is silane, in the case of silicon deposition. Another option to avoid both the deposition directly onto the template and the local etching of the template is the proper formation of the contact area that the template shares with the susceptor. Low contact area in conjunction with suitably large radii at the contact area are preferable. This, in conjunction with suitable heater arrangements, is required to enable a uniform thermal ramp and profile within and between templates.

As for the epitaxial deposition process, the TFSS that is deposited epitaxially may contain an in-situ emitter, deposited in the semiconductor deposition chamber. The emitter may also be added later as an ex-situ emitter outside of the epitaxy chamber. The structure on the template may be with the emitter up or down. The epitaxial or non-epitaxial deposition may or may not contain a suitable dopant gradient designed to aid the desired flow of generated carriers through the device.

This so fabricated layer structure of deposited semiconductor on a weakened layer on a high temperature capable template is extremely valuable. It allows for carrying a thin film on a solid template and allows much flexibility for what is in the following called on-template processing.

In such on-template processing, the template serves as a carrier to move and support the thin and fragile TFSS throughout several on-template process steps, including but not limited to the following: thermal processes such as oxidation or film deposition, including but not limited to thermal oxidation; nanosecond (ns), picoseconds (ps) or other laser processes, such as scribing, doping, or ablation; chemical vapor deposition (CVD) and physical vapor deposition (PVD) processes; lithography, screen printing, ink jet printing, spray coating or etching, immersion clean, etch or deposition (such as plating), lamination, die attach or bonding, releasing, wet chemical texturing or dry texturing of the surface, rinsing, cleaning and drying of the surface. A unique quality here is that the template is clean and solar-cell-compatible, rigid and sturdy, high-temperature-capable, and reworkable.

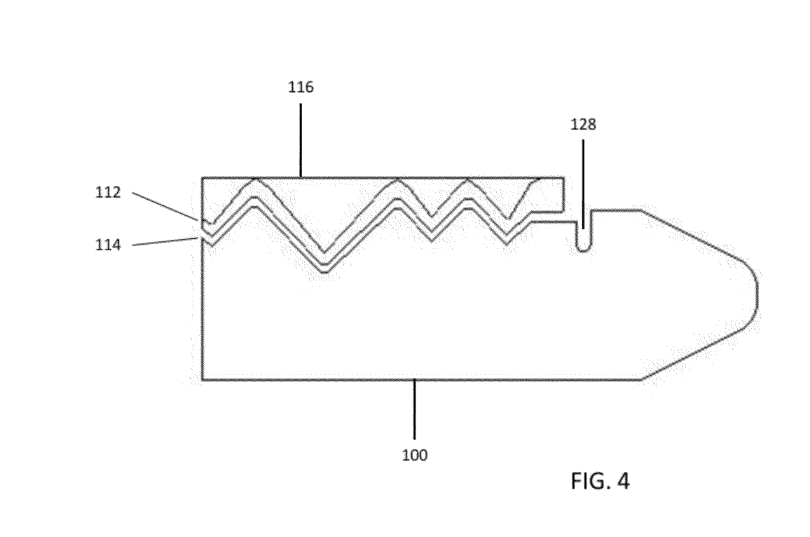

After suitable on-template processing, the TFSS can be released from the template carrier. A conceptual diagram of the release of TFSS 116 from template 100 is shown in FIG. 4. The release can be carried out either with or without the use of a temporary or permanent reinforcement plate, which is attached to the epi layer prior to the release. The reinforcement plate may or may not at this point or later contain structures, such as dielectrics or conductive materials. If used, the reinforcement plate may contain perforations or otherwise a plurality of conductive locations enabling the electrical contacting of the TFSS through or around the reinforcement plate, such perforations being present either at the time of TFSS release or formed at a later point. Suitable reinforcement materials may include silicon, glass, silicon-aluminum alloys, plastics or polymers such as prepreg or other dielectric adhesives, metals such as aluminum, ceramics or combinations thereof. At a suitable point prior to release, the definition or border cutting of the TFSS area to be released can be accomplished for instance using a laser. FIG. 4 shows border cut 128 surrounding TFSS 116.

This border cutting can be performed before or after the release of the TFSS. It may be advantageous to do cutting both before and after the release, depending on reinforcement process and materials. The border cutting also serves to weaken the thin TFSS and thus facilitate easier release. Another potential method for facilitating easier release is the use of a grinding or otherwise abrasive method, preferably applied to the edge of the template. By doing so, the TFSS epitaxial layer region at the edge of the template can serve as the weak point, from which release can be initiated. Such pre-release grinding can also facilitate the flow of air into the weakened area between TFSS 116 and template 100, thereby allowing pressure equalization and removing pressure-differential-induced resistance to the release motion. The release itself can be carried out by exploiting the presence of local weak areas which serve as initiation locations for the release.

Optionally, a pulsed force, for instance by pulsating the vacuum on either side of the template and substrate sandwich, can be applied. In this way, the release process can be extended across location and time (not unlike opening a zipper), rather than having to overcome the whole area bond force plus the atmospheric pressure holding force on the template. Alternatively, the release can be initiated at an edge or a corner of a substrate and then proceed from there, while in the process keeping the template and the partially released TFSS essentially parallel, in order to avoid small curvature radii, which can contribute to excessive stresses and potential cracking of the active TFSS layer.

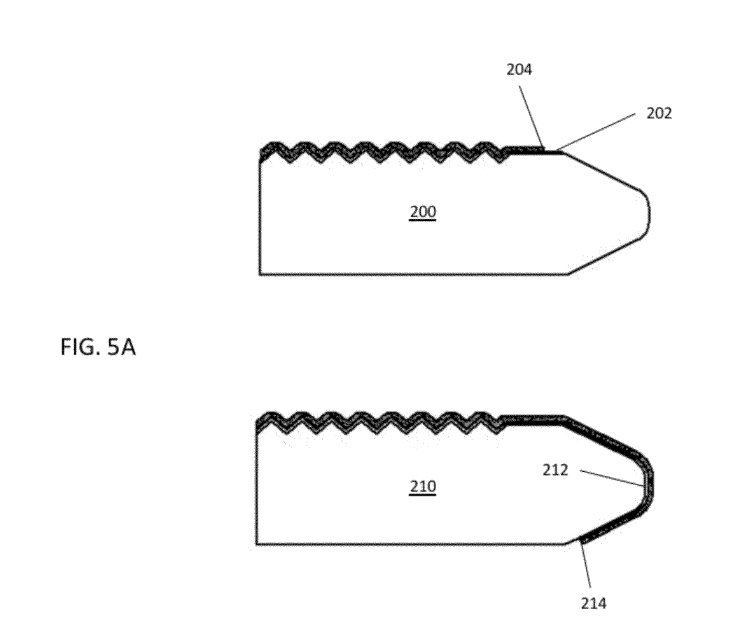

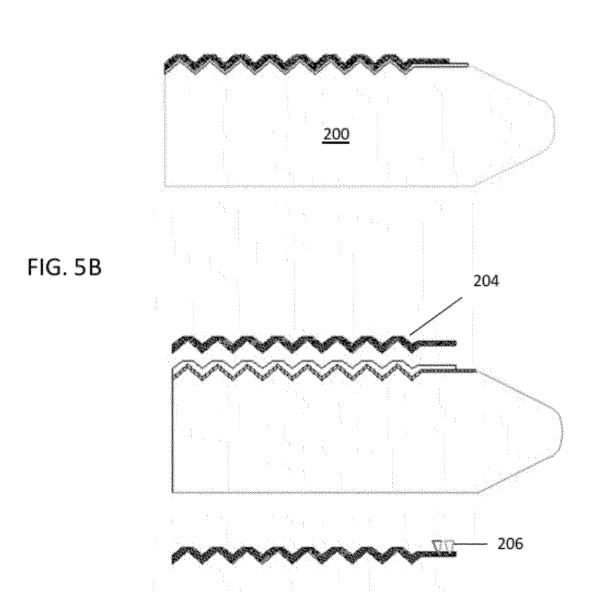

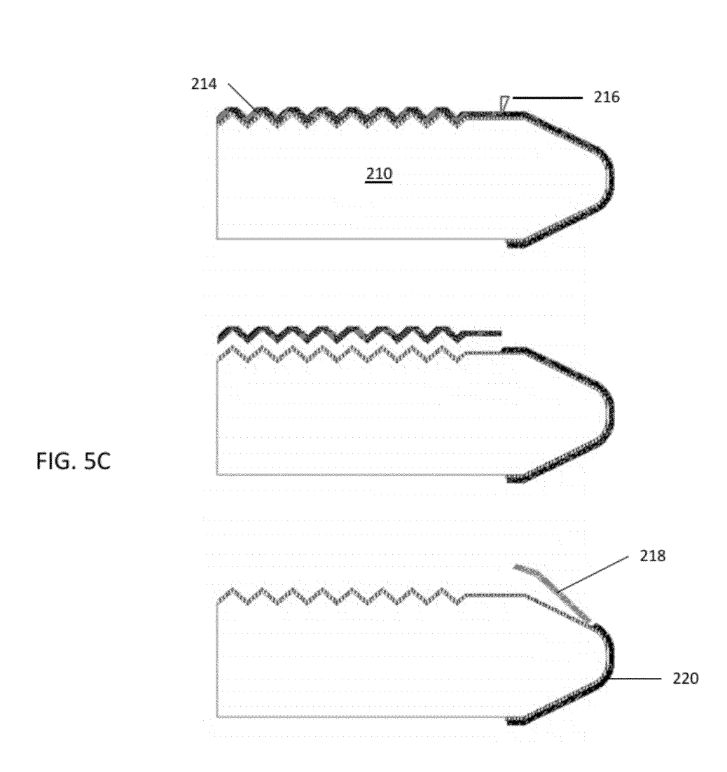

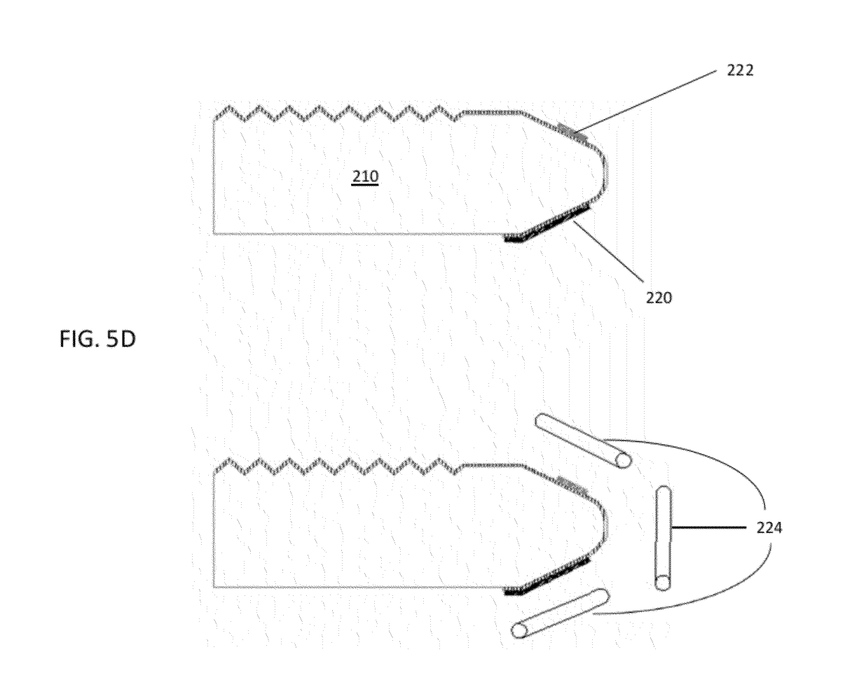

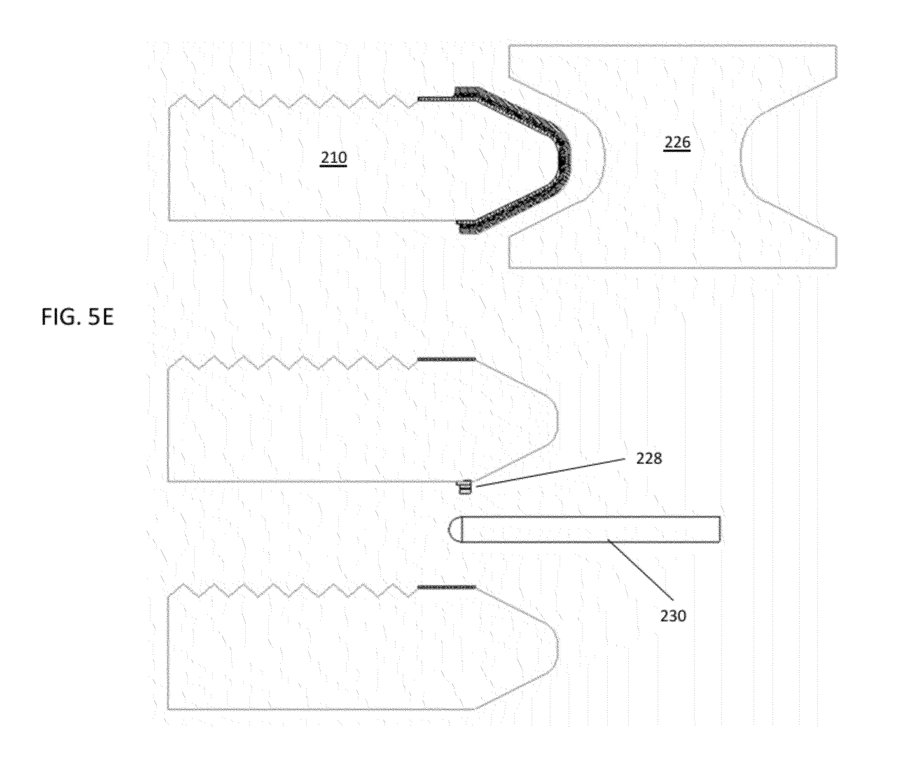

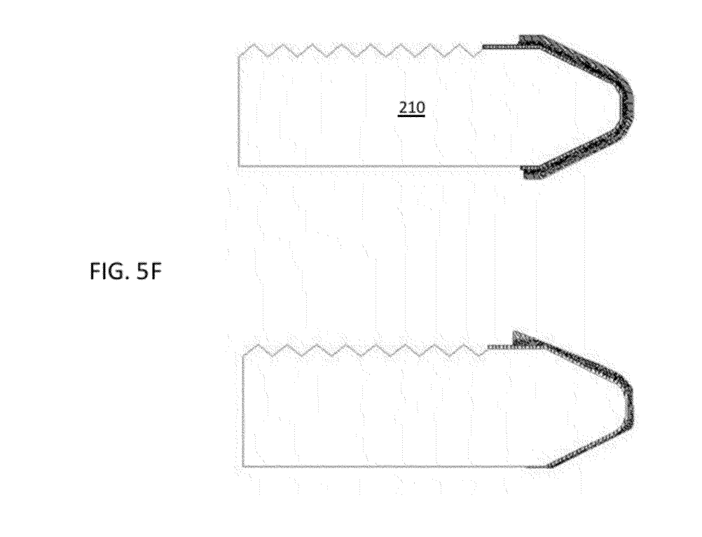

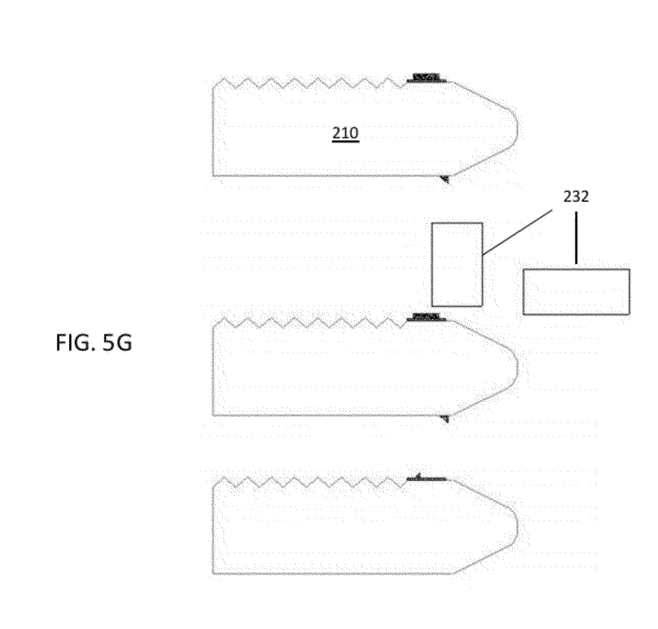

After release of the active TFSS there may be residual deposited thin film that is remaining outside of the active area, especially if the template is somewhat oversized with respect to the active TFSS. FIG. 5A shows two possibilities. Template 200 has a layer of porous semiconductor 202 which extends beyond the edge of TFSS 204. This does not present a problem for release.

However, a typical CVD deposition process can deposit material not just on the front side, but depending on the design, also on the edges and the back side of the template. The extent of the film coverage is illustrated in template 210. Thick deposition of semiconductor layer in the bevel area can be undesirable. Depending on the process, deposition on the backside can be detrimental for subsequent processing, or desired, if the backside deposition yields a comparable film to the front side deposition in the case of double side processing. Several precautions may be taken in order to wind up with a template like template 200 instead of template 210. One mode for avoiding or minimizing backside and bevel deposition is to use a neutral gas, such as hydrogen, as a purge gas in the vicinity of the edge and the backside of the template during the deposition step. Another mode for avoiding or minimizing backside and bevel deposition is to use a shadow mask that shadows the area where deposition is not desired from the deposition gas. A third mode for reducing backside and bevel deposition is to use susceptor designs with large surface area or otherwise optimized geometries which can serve to preferentially deposit material from the gas phase, thereby depleting the deposition gas in areas where deposition is not desired. Deposition processes may have preferred locations and directions where more or less material is deposited in undesirable areas. It may be advantageous to symmetrize the deposition of the undesired material across several re-uses of the same template. For that purpose, the template orientation can be tracked where needed, and dedicated changes of orientation or location can be programmed as part of a production flow.

In template 210, porous silicon layer 212 wraps partially around the edge of the template, but TFSS 214 wraps around even farther. Under circumstances where the TFSS extends beyond the edge of the porous semiconductor, other methods may be employed to remove the section of the TFSS that directly contacts the template.

FIG. 5B demonstrates TFSS release in the case of template 200. TFSS 204 is released, leaving little or no edge debris. After release, TFSS 204 may be cut to size by laser 206.

FIG. 5C shows template 210, the case where the TFSS extends beyond the edge of the porous semiconductor layer or where the porous semiconductor is not formed with porosities or thickness in the bevel region that are adequate for easy release of the TFSS. TFSS 214 is cut to size by laser 216 and then released from template 210. After release, a residual film must be subsequently removed. Section 218, which is bonded to a porous semiconductor layer and not directly to template 210, may be removed by use of compressed air, high or elevated pressure water or other suitable fluid, a taping-detaping process, by sonic (ultra- or megasonic) energy, or by a machining process such as grinding or lapping the residual film off the template. The grinding can for instance be accomplished using a grinding material that is abrasive and has a suitable hardness with respect to that of the semiconductor or by a soft material, which shears off the excess thin film deposit. The latter makes use of the fact that the bond force of the excess material is lower and governed by the weakened layer between the thin film and the template. The removal of excess thin film can also occur by suitable chemical etching. Suitable chemical etching can be selected to yield good dopant concentration or composition based selectivity between deposited film and template. It can also make use of a directed, localized etch.

The removal of the residual deposited thin film can be accomplished on a single wafer basis or in a batch mode. The removal processes described so far are designed to remove material at least in the flat part of the template outside of the active area and extending onto the bevel of the template at the bevel edge. Other methods may be used to remove the remainder 220 of the TFSS that is bonded directly to template 210 due to local lacking or imperfect quality of the porous semiconductor layer.

Independent of the precautions mentioned above, it may be advantageous to remove excess deposited material in the bevel or the backside area. This removal of excess deposited material may be carried out after each re-use cycle or after several re-use cycles and may be repeated throughout the lifetime of the template. FIG. 5D shows the use of grinding tape 224 to remove remainder 220 and local imperfection 222, and FIG. 5E shows the use of a machine tool for a grinding, polishing, or otherwise abrading device. With such a device, the excess deposited material in the bevel or backside area can be reduced or completely removed. For the case of the tape based grinder, the template may be spun in the presence of a tape, which is typically embedded with diamond or silicon carbide. For non-round template geometries, such as squares or pseudo-squares, the removal setup should be a different one, where, for instance, the template would not be spun, but moved from side to side, swiveled, or oscillated; or the tape holding/feeding mechanism may be moved, swiveled or oscillated. The removal process can be tuned to preferentially remove material in areas where more excess material has been deposited. Removal of deposited material at the different points around the bevel or backside area are accomplished by applying the tool, tape or sheet at different angles, pressures or positions towards the template. Other removal implementations for deposited material will be apparent to those with ordinary skill in the art. An alternative process to this type of mechanical removal of excess deposit from the template is the use of suitable chemistry which is applied locally with the goal of removing the excess deposit from the template.

In FIG. 5E, precision grinding wheel 226 (or a polishing wheel or slurry) is used to remove the film around the edge of template 210. However, this may leave backside residue 228, which may then be removed by, for example the use of backside grinder 230. It is also envisioned to combine the function of a bevel grinding wheel with that of an edge backside grinding wheel into one tool.

Another alternative process to the tape, sheet or precision bevel grind/polish step is the use of a laser, either direct or water-jet-guided, to remove excess deposition at the bevel and the underside of the template and reshape the bevel. The effect of a laser based bevel material removal process is shown in FIG. 5F. This method may have the advantage of allowing particularly precise dimensional control. A combination of the above methods is also likely. As shown, little or none of template 210 has been removed by the laser edge ablation employed in FIG. 5F.

In some cases, the processes described above in conjunction with FIG. 5C-5E will still leave some unwanted additional TFSS material on the front side of the template as well as the back side. In this case, as shown in FIG. 5G, grinders 232 may be used to remove that material. If this is not done, the remaining front side TFSS material may cause the next TFSS produced on template 210 to “lock” to that point, making release more difficult. By removing the excess material before reusing the template, this concern may be alleviated.

After the removal of the undesired TFSS material by whatever method, a typical flow may include re-use cleaning, which serves several purposes: first, to bring the template into a re-usable condition, capable of withstanding repeated re-uses; second, to remove remnants of the sacrificial release layer; next, to remove metallic contaminants that would be detrimental to the lifetimes of the subsequent TFSSs to be deposited on the same template; and finally, to remove detrimental remnants of any on-template processes, such as organic or metal-containing residues. Typically, after the re-use cleaning, the template is subjected again to the porous semiconductor formation process, thereby forming another sacrificial release layer. This is then again followed by the deposition of the thin film to be released. Subsequent processing continues as described above.

Residual deposition extending onto the backside of the template may be detrimental to further processing and may accumulate as the template is subjected repeatedly to the sacrificial layer formation/deposition/further processing/release/post-release treatment processing. Residual deposition on the backside can cause local stress points and unsmooth template surfaces which are detrimental to handling and which may increase the propensity of the template to break. Therefore, the avoidance (described above) or removal of backside deposited material may be advantageous. This may be carried out after each re-use cycle or after several re-use cycles and may be repeated throughout the lifetime of the template. These methods can be done either by removing material from the complete backside area or by removing only locally at the wafer edge the material deposited mainly at the edge of the backside.

The template is a highly valuable commodity in the overall process. Therefore, any process that serves to extend the potential number of deposition cycles that the template can sustain adds substantially to the value proposition. Therefore, in the case of defective processing on the template or incomplete release or removal of the TFSS film, the template can be subjected to a reconditioning process. This reconditioning process may consist of grinding and/or polishing of the full area of the template or of only the problematic portions of the template. After successful reconditioning, the templates can be re-entered into the process loop and re-use can be resumed.

Grinding and/or polishing can be accomplished using a single side or double side grinder/polisher. The grinding/polishing process is chosen according to the necessity of surface finish. The TFSS described above which later forms the substrate for the solar cell does not rely on a mirror polished surface finish of the substrate. It is therefore important to point out that the porous semiconductor sacrificial layer can be formed on a template surface that does not have to start out as a mirror polished semiconductor surface. As it is not known beforehand at what stage an imperfect processing of the substrate occurs and as an HVM-compatible grind/polish process uses up the least amount of material from the starting template if the thickness is known, it is advantageous to inspect the templates at one stage subsequent to the release process, and sort them into thickness ranges, such that a multitude of templates can be processed in a grinder/polisher at the same time, to the same target thickness. The above sorting for thickness and for local residue from the deposition can be done concurrently with suitable equipment, such as optical, capacitive or gas back pressure based sensing.

The TFSS that was released from the template carrier and which may already have several processes applied to it while on the template can be processed further after the release. There are several possible embodiments for the TFSS and its further handling: for sufficient layer thickness, the TFSS can be self-supporting and handled through further processes as is. If the template that was used to deposit the TFSS material onto was structured to form a three-dimensional structure, such as an array of pyramids, prisms or other three-dimensional geometries, then the TFSS may be self-supporting even if the amount of deposited TFSS material is very small. This structural feature is a potential advantage of the three-dimensional template and TFSS. If the layer thickness is not sufficient for the TFSS to be self-supporting, then the TFSS can be supported during further processing via a suitable support plate.

Those with ordinary skill in the art will recognize that the disclosed embodiments have relevance to a wide variety of areas in addition to those specific examples described above.

The foregoing description of the exemplary embodiments is provided to enable any person skilled in the art to make or use the claimed subject matter. Various modifications to these embodiments will be readily apparent to those skilled in the art, and the generic principles defined herein may be applied to other embodiments without the use of the innovative faculty. Thus, the claimed subject matter is not intended to be limited to the embodiments shown herein but is to be accorded the widest scope consistent with the principles and novel features disclosed herein.

It is intended that all such additional systems, methods, features, and advantages that are included within this description be within the scope of the claims.

What is claimed is:

1. A method for making a thin film semiconductor substrate, said method comprising:
providing a reusable semiconductor template;
forming a sacrificial release layer on a front side of said reusable semiconductor template;
epitaxially depositing a thin film semiconductor substrate conformally to said sacrificial release layer;
releasing said thin film semiconductor substrate from said reusable semiconductor template by separation at said sacrificial release layer; and
reconditioning said reusable semiconductor template to remove excess epitaxially deposited thin film semiconductor substrate material to enable production of a second thin film semiconductor substrate.

2. The method of claim 1, wherein said semiconductor comprises silicon.

3. The method of claim 2, wherein said silicon comprises monocrystalline silicon.

4. The method of claim 1, further comprising using a laser to define a boundary of said thin film semiconductor substrate prior to said step of releasing, thereby aiding said step of releasing.

5. The method of claim 1, further comprising using bevel grinding of said template containing said epitaxially deposited thin film semiconductor substrate to define a boundary of said thin film semiconductor substrate prior to said step of releasing, thereby aiding said step of releasing.

6. The method of claim 1, wherein said step of reconditioning comprises polishing or grinding epitaxially deposited material from a beveled edge of said reusable semiconductor template.

7. The method of claim 1, wherein said step of reconditioning comprises lapping or grinding epitaxially deposited material from a surface of said reusable semiconductor template.

8. The method of claim 1, wherein said step of reconditioning comprises removing epitaxially deposited material from a back side of said reusable semiconductor template.

9. The method of claim 1, wherein said step of reconditioning comprises tape bevel grinding or polishing epitaxially deposited material from a beveled edge of said reusable semiconductor template.

10. The method of claim 1, wherein said step of reconditioning comprises removing epitaxially deposited material from said reusable semiconductor template using laser ablation.

11. The method of claim 10, wherein said laser ablation uses a water jet guide.

12. The method of claim 1, wherein said step of reconditioning comprises removing epitaxially deposited material from said reusable semiconductor template using sonication.

13. The method of claim 1, wherein said step of reconditioning comprises removing epitaxially deposited material from said reusable semiconductor template high pressure water or high pressure gas.

14. The method of claim 1, wherein said step of reconditioning comprises removing epitaxially deposited material from said reusable semiconductor template using kiss grinding.

15. The method of claim 1, wherein said step of reconditioning comprises removing epitaxially deposited material from said a beveled edge of said reusable semiconductor template using programmable precision bevel grinding.

16. The method of claim 1, wherein said reusable semiconductor template is tracked within the production process and repeated depositions are carried out in different orientations of said template in order to have symmetric edge and backside depositions.

17. The method of claim 1, further comprising measuring the thickness or the weight of said reusable semicondor template prior to a reconditioning area grinding or lapping, in order to determine necessary material removal at said grinding or lapping step or in order to bin it with like templates for subsequent batch lapping or grinding processes.

18. A method for making a thin film semiconductor substrate, said method comprising:
providing a reusable semiconductor template;
forming a sacrificial release layer on a front side of said reusable semiconductor template;
epitaxially depositing a thin film semiconductor substrate conformally to said sacrificial release layer, said depositing step achieving a reduced back side and edge deposition via at least one of a backside gas purging process or an edge shadow mask; and
releasing said thin film semiconductor substrate from said reusable semiconductor template by separation at said sacrificial release layer.

19. A method for making a thin film semiconductor substrate, said method comprising:
providing a reusable semiconductor template;
forming a sacrificial release layer on a front side of said reusable semiconductor template;
epitaxially depositing a thin film semiconductor substrate conformally to said sacrificial release layer;
releasing said thin film semiconductor substrate from said reusable semiconductor template by separation at said sacrificial release layer;
performing at least one of a silicon etch, a metal clean, and an organic clean on said reusable semiconductor template to remove residue from previously produced and released thin film semiconductor substrates and on-template processes performed on said thin film semiconductor substrates; and
reconditioning said reusable semiconductor template to enable production of a second thin film semiconductor substrate.
